(19) United States
(12) Patent Application Publication
(10) Pub. No.: US 2023/0350778 A1
(43) Pub. Date: Nov. 2, 2023

(54) SIMULATION EVALUATION PIPELINE

(71) Applicant: EMBARK TRUCKS, INC., San Francisco, CA (US)

(72) Inventors: Zhuoran LU, San Francisco, CA (US); Taylor ENGLAND, San Francisco, CA (US)

(21) Appl. No.: 17/732,847

(22) Filed: Apr. 29, 2022

(51) Int. Cl. G06F 11/34; G06F 11/36; G06F 8/10

(52) U.S. Cl. CPC G06F 11/3457; G06F 11/3616; G06F 8/10

(57) ABSTRACT

A system and method including receiving an indication to execute an evaluation of a simulation of an autonomous vehicle performing one or more actions; retrieving a data record for a simulation of the autonomous vehicle performing the one or more actions; determining at least one metric based on an evaluation result of applying a set of requirements for the one or more actions to the data record of the simulation; storing the at least one metric for the set of requirements in a memory.

### BACKGROUND

Autonomous vehicles are motor vehicles capable of performing one or more necessary driving functions without a human driver's input, generally including Level 2 or higher capabilities as set generally described in SAE International's J3016 Standard and including, in certain embodiments, self-driving trucks that include sensors, devices, and systems that may function together to generate sensor data indicative of various parameter values related to the position, speed, operating characteristics of the vehicle, and a state of the vehicle, including data generated in response to various objects, situations, and environments encountered by the autonomous vehicle during the operation thereof.

Vast amounts of sensor data may be generated and recorded by an autonomous vehicle during an on-road run (i.e., one or more driving sessions, trips, etc.) of the vehicle. In some instances, such as a test run on a test track, various aspects of the autonomous vehicle's on-road performance might be tested or evaluated to determine whether the autonomous vehicle performs in an appropriate, safe, and timely manner in response to the situation(s) encountered by the autonomous vehicle. Requirements may be defined and used in the evaluation of the vehicle's on-road performance, where a result of the evaluation may indicate whether the autonomous vehicle passed or failed to satisfy the requirements.

In some instances, there might be a desire or need to evaluate the performance of an autonomous vehicle in a simulation environment instead of on a track or other on-road environment.

As such, there exists a need for an efficient and robust system and method to generate a pipeline that evaluates simulation results of an autonomous vehicle's behavior in a comprehensive set of scenarios.

### BRIEF DESCRIPTION OF THE DRAWINGS

Features and advantages of the example embodiments, and the manner in which the same are accomplished, will become more readily apparent with reference to the following detailed description taken in conjunction with the accompanying drawings.

FIG. 1 is an illustrative block diagram of a control system that may be deployed in a vehicle, in accordance with an example embodiment;

FIGS. 2A-2C are illustrative depictions of exterior views of a semi-truck, in accordance with example embodiments;

FIG. 3 is an illustrative depiction of an autonomous vehicle on a road, in accordance with an example embodiment;

FIG. 4 is an illustrative depiction of a framework for a simulation evaluation pipeline, in accordance with an example embodiment;

FIG. 5 is an illustrative depiction of a database schema, in accordance with an example embodiment;

FIG. 6 is an illustrative flow diagram of an example simulation pipeline process, in accordance with an example embodiment;

FIG. 7 an illustrative example of an architecture in which aspects of the present disclosure may be applied, in accordance with an example embodiment; and

FIG. 8 an illustrative block diagram of a computing system, in accordance with an example embodiment.

Throughout the drawings and the detailed description, unless otherwise described, the same drawing reference numerals will be understood to refer to the same elements, features, and structures. The relative size and depiction of these elements may be exaggerated or adjusted for clarity, illustration, and/or convenience.

### DETAILED DESCRIPTION

In the following description, specific details are set forth in order to provide a thorough understanding of the various example embodiments. It should be appreciated that various modifications to the embodiments will be readily apparent to those skilled in the art, and the one or more principles defined herein may be applied to other embodiments and applications without departing from the spirit and scope of the present disclosure. Moreover, in the following description, numerous details are set forth for the purpose of explanation. However, one of ordinary skills in the art should understand that embodiments may be practiced without the use of these specific details. In other instances, well-known structures, methods, procedures, components, and circuits are not shown or described so as not to obscure the description with unnecessary detail. Thus, the present disclosure is not intended to be limited to the embodiments shown but is to be accorded the widest scope consistent with the principles and features disclosed herein.

For convenience and ease of exposition, a number of terms will be used herein. For example, the term “semi-truck” will be used to refer to a vehicle in which systems of the example embodiments may be used. The terms “semi-truck”, “truck”, “tractor”, “vehicle” and “semi” may be used interchangeably herein. However, it is understood that the scope of the invention is not limited to use within semi-trucks.

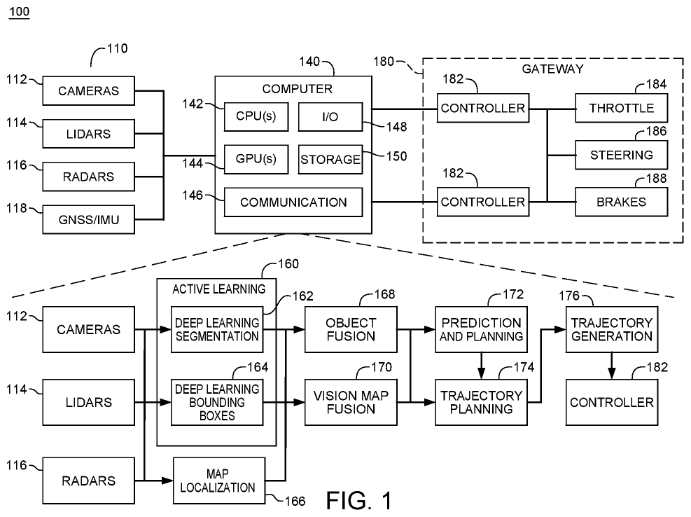

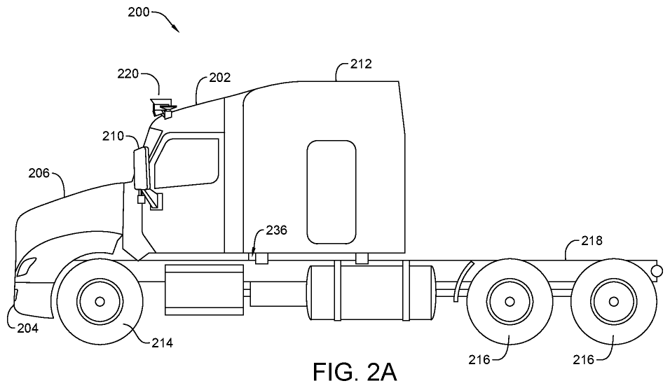

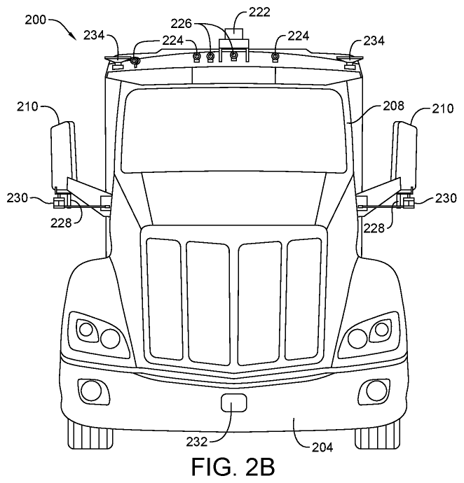

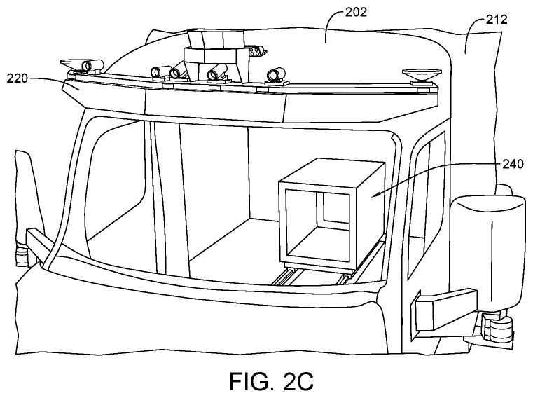

FIG. 1 illustrates a control system 100 that may be deployed in and comprise an autonomous vehicle (AV) such as, for example though not limited to, a semi-truck 200 depicted in FIGS. 2A-2C, in accordance with an example embodiment. Referring to FIG. 1, the control system 100 may include sensors 110 that collect data and information provided to a computer system 140 to perform operations including, for example, control operations that control components of the vehicle via a gateway 180. Pursuant to some embodiments, gateway 180 is configured to allow the computer system 140 to control different components from different manufacturers.

Computer system 140 may be configured with one or more central processing units (CPUs) 142 to perform processing, including processing to implement features of embodiments of the present invention as described elsewhere herein, as well as to receive sensor data from sensors 110 for use in generating control signals to control one or more actuators or other controllers associated with systems of the vehicle in which control system 100 is deployed (e.g., actuators or controllers allowing control of a throttle 184, steering systems 186, brakes 188 and/or other devices and systems). In general, control system 100 may be configured to operate the vehicle (e.g., semi-truck 200) in an autonomous (or semi-autonomous) mode of operation.

For example, control system 100 may be operated to capture images from one or more cameras 112 mounted at various locations of semi-truck 200 and perform processing (e.g., image processing) on those captured images to identify objects proximate to or in a path of the semi-truck 200. In some aspects, one or more lidars 114 and radar 116 sensors may be positioned on the vehicle to sense or detect the presence and volume of objects proximate to or in the path of the semi-truck 200. Other sensors may also be positioned or mounted at various locations of the semi-truck 200 to capture other information such as position data. For example, the sensors might include one or more satellite positioning sensors and/or inertial navigation systems such as GNSS/IMU 118. A Global Navigation Satellite System (GNSS) is a space-based system of satellites that provides the location information (longitude, latitude, altitude) and time information in all weather conditions, anywhere on or near the Earth to devices called GNSS receivers. GPS is the world's most used GNSS system and may be used interchangeably with GNSS herein. An inertial measurement unit (“IMU”) is an inertial navigation system. In general, an inertial navigation system (“INS”) measures and integrates orientation, position, velocities, and accelerations of a moving object. An INS integrates the measured data, where a GNSS is used as a correction to the integration error of the INS orientation calculation. Any number of different types of GNSS/IMU 118 sensors may be used in conjunction with features of the present invention.

The data collected by each of the sensors 110 may be processed by computer system 140 to generate control signals that might be used to control an operation of the semi-truck 200. For example, images and location information may be processed to identify or detect objects around or in the path of the semi-truck 200 and control signals may be transmitted to adjust throttle 184, steering 186, and/or brakes 188 via controller(s) 182, as needed to safely operate the semi-truck 200 in an autonomous or semi-autonomous manner. Note that while illustrative example sensors, actuators, and other vehicle systems and devices are shown in FIG. 1, those skilled in the art, upon reading the present disclosure, will appreciate that other sensors, actuators, and systems may also be included in system 100 consistent with the present disclosure. For example, in some embodiments, actuators that provide a mechanism to allow control of a transmission of a vehicle (e.g., semi-truck 200) may also be provided.

Control system 100 may include a computer system 140 (e.g., a computer server) that is configured to provide a computing environment in which one or more software, firmware, and control applications (e.g., items 160-182) may be executed to perform at least some of the processing described herein. In some embodiments, computer system 140 includes components that are deployed on a vehicle (e.g., deployed in a systems rack 240 positioned within a sleeper compartment 212 of the semi-truck as shown in FIG. 2C). Computer system 140 may be in communication with other computer systems (not shown) that might be local to and/or remote from the semi-truck 200 (e.g., computer system 140 might communicate with one or more remote terrestrial or cloud-based computer system via a wireless communication network connection).

According to various embodiments described herein, computer system 140 may be implemented as a server. In some embodiments, computer system 140 may be configured using any of a number of computing systems, environments, and/or configurations such as, but not limited to, personal computer systems, cloud platforms, server computer systems, thin clients, thick clients, hand-held or laptop devices, tablets, smart phones, databases, multiprocessor systems, microprocessor-based systems, set top boxes, programmable consumer electronics, network PCs, minicomputer systems, mainframe computer systems, distributed cloud computing environments, and the like, which may include any of the above systems or devices, and the like.

Different software applications or components might be executed by computer system 140 and control system 100. For example, as shown at active learning component 160, applications may be provided that perform active learning machine processing to process images captured by one or more cameras 112 and information obtained by lidars 114. For example, image data may be processed using deep learning segmentation models 162 to identify objects of interest in the captured images (e.g., other vehicles, construction signs, etc.). In some aspects herein, deep learning segmentation may be used to identify lane points within the lidar scan. As an example, the system may use an intensity-based voxel filter to identify lane points within the lidar scan. Lidar data may be processed by machine learning applications 164 to draw or identify bounding boxes on image data to identify objects of interest located by the lidar sensors.

Information output from the machine learning applications may be provided as inputs to object fusion 168 and vision map fusion 170 software components that may perform processing to predict the actions of other road users and to fuse local vehicle poses with global map geometry in real-time, enabling on-the-fly map corrections. The outputs from the machine learning applications may be supplemented with information from radars 116 and map localization 166 application data (as well as with positioning data). In some aspects, these applications allow control system 100 to be less map reliant and more capable of handling a constantly changing road environment. Further, by correcting any map errors on-the-fly, control system 100 may facilitate safer, more scalable and more efficient operations as compared to alternative map-centric approaches.

Information is provided to prediction and planning application 172 that provides input to trajectory planning 174 components allowing a trajectory to be generated by trajectory generation system 176 in real time based on interactions and predicted interactions between the semi-truck 200 and other relevant vehicles in the trucks operating environment. In some embodiments, for example, control system 100 generates a sixty second planning horizon, analyzing relevant actors and available trajectories. The plan that best fits multiple criteria (including safety, comfort and route preferences) may be selected and any relevant control inputs needed to implement the plan are provided to controller(s) 182 to control the movement of the semi-truck 200.

In some embodiments, these disclosed applications or components (as well as other components or flows described herein) may be implemented in hardware, in a computer program executed by a processor, in firmware, or in a combination of the above, unless otherwise specified. In some instances, a computer program may be embodied on a computer readable medium, such as a storage medium or storage device. For example, a computer program, code, or instructions may reside in random access memory (“RAM”), flash memory, read-only memory (“ROM”), erasable programmable read-only memory (“EPROM”), electrically erasable programmable read-only memory (“EEPROM”), registers, hard disk, a removable disk, a compact disk read-only memory (“CD-ROM”), or any other form of non-transitory storage medium known in the art.

A non-transitory storage medium may be coupled to a processor such that the processor may read information from, and write information to, the storage medium. In an alternative, the storage medium may be integral to the processor. The processor and the storage medium may reside in an application specific integrated circuit (“ASIC”). In an alternative embodiment, the processor and the storage medium may reside as discrete components. For example, FIG. 1 illustrates an example computer system 140 that may represent or be integrated in any of the components disclosed hereinbelow, etc. As such, FIG. 1 is not intended to suggest any limitation as to the scope of use or functionality of embodiments of a system and method disclosed herein. Computer system 140 is capable of being implemented and/or performing any of the functionality disclosed herein.

Computer system 140 may be described in the general context of computer system-executable instructions, such as program modules, being executed by a computer system. Generally, program modules may include routines, programs, objects, components, logic, data structures, and so on that perform particular tasks or implement particular abstract data types. Computer system 140 may be implemented in distributed cloud computing environments where tasks are performed by remote processing devices that are linked through a communications network. In a distributed cloud computing environment, program modules may be located in both local and remote computer system storage media including non-transitory memory storage devices.

Referring to FIG. 1, computer system 140 is shown in the form of a general-purpose computing device. The components of the computer system 140 may include, but are not limited to, one or more processors (e.g., CPUs 142 and GPUs 144), a communication interface 146, one or more input/output interfaces 148, and one or more storage devices 150. Although not shown, computer system 140 may also include a system bus that couples various system components, including system memory, to CPUs 142. In some embodiments, input/output (I/O) interfaces 148 may also include a network interface. For example, in some embodiments, some or all of the components of the control system 100 may be in communication via a controller area network (“CAN”) bus or the like interconnecting the various components inside of the vehicle in which control system 100 is deployed and associated with.

In some embodiments, storage device 150 may include a variety of types and forms of non-transitory computer readable media. Such media may be any available media that is accessible by computer system/server, and it may include both volatile and non-volatile media, removable and non-removable media. System memory, in one embodiment, implements the processes represented by the flow diagram(s) of the other figures herein. The system memory can include computer system readable media in the form of volatile memory, such as random access memory (RAM) and/or cache memory. As another example, storage device 150 can read and write to a non-removable, non-volatile magnetic media (not shown and typically called a “hard drive”). Although not shown, the storage device 150 may include one or more removable non-volatile disk drives such as magnetic, tape or optical disk drives. In such instances, each can be connected to the bus by one or more data media interfaces. Storage device 150 may include at least one program product having a set (e.g., at least one) of program modules, code, and/or instructions that are configured to carry out the functions of various embodiments of the application.

FIGS. 2A-2C are illustrative depictions of exterior views of a semi-truck 200 that may be associated with or used in accordance with example embodiments. Semi-truck 200 is shown for illustrative purposes only. As such, those skilled in the art, upon reading the present disclosure, will appreciate that embodiments may be used in conjunction with a number of different types of vehicles and are not limited to a vehicle of the type illustrated in FIGS. 2A-2C. The example semi-truck 200 shown in FIGS. 2A-2C is one style of truck configuration that is common in North American that includes an engine 206 forward of a cab 202, a steering axle 214, and two drive axles 216. A trailer (not shown) may typically be attached to semi-truck 200 via a fifth-wheel trailer coupling that is provided on a frame 218 and positioned over drive axles 216. A sleeper compartment 212 may be positioned behind cab 202, as shown in 2A and 2C. FIGS. 2A-2C further illustrate a number of sensors that are positioned at different locations of semi-truck 200. For example, one or more sensors may be mounted on a roof of cab 202 on a sensor rack 220. Sensors may also be mounted on side mirrors 210, as well as other locations of the semi-truck. Sensors may be mounted on a bumper 204, as well as on the side of the cab 202 and other locations. For example, a rear facing radar 236 is shown as being mounted on a side of the cab 202 in FIG. 2A. Embodiments may be used with other configurations of trucks and other vehicles (e.g., such as semi-trucks having a cab over or cab forward configuration or the like). In general, and without limiting embodiments of the present disclosure, features of the present invention may be used with desirable results in vehicles that carry cargo over long distances, such as long-haul semi-truck routes.

FIG. 2B is a front view of the semi-truck 200 and illustrates a number of sensors and sensor locations. The sensor rack 220 may secure and position several sensors above windshield 208 including a long range lidar 222, long range cameras 224, GPS antennas 234, and mid-range front facing cameras 226. Side mirrors 210 may provide mounting locations for rear-facing cameras 228 and mid-range lidar 230. A front radar 232 may be mounted on bumper 204. Other sensors (including those shown and some not shown) may be mounted or installed on other locations of semi-truck 200. As such, the locations and mounts depicted in FIGS. 2A-2C are for illustrative purposes only.

Referring now to FIG. 2C, a partial view of semi-truck 200 is shown that depicts some aspects of an interior of cab 202 and the sleeper compartment 212. In some embodiments, portion(s) of control system 100 of FIG. 1 might be deployed in a systems rack 240 in the sleeper compartment 212, allowing easy access to components of the control system 100 for maintenance and operation.

Particular aspects of the present disclosure relate to a method and system providing a framework or architecture for a simulation pipeline to evaluate a performance of an autonomous vehicle, AV, (e.g., a truck similar to that disclosed in FIGS. 1 and 2A-2C) in a simulation environment. The disclosed framework may be used to develop a simulation evaluation pipeline that can evaluate simulation results against both system requirements and prior simulation pipeline software feature branches. Aspects of the present disclosure provide, in general, a framework to build or otherwise generate an offline evaluation pipeline that functions to examine simulated scenarios related to an AV against defined system requirements, store results of the evaluation, present the results and visualizations or analytics derived therefrom. In some embodiments, the framework might provide a mechanism to track performances over a period of time.

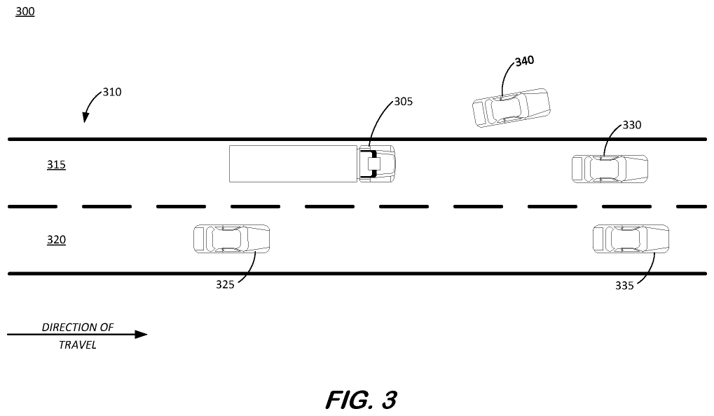

FIG. 3 is an illustrative depiction of a scene 300 including an autonomous vehicle 305 associated with or otherwise related to a simulation that might be evaluated, in accordance with an example embodiment. The AV 305 depicted in FIG. 3 including a cab and a trailer may be the same as or similar to the truck disclosed in FIGS. 1 and 2A-2C above. In some embodiments, computer 140 may be configured to support an implementation of some of the processes (or portions thereof) related to supporting an evaluation of executed simulation results against system requirements, as disclosed in detail below. For example, a computer onboard AV 140 may be responsible for obtaining and storing sensor and other operational data over the span of a run of the truck in a memory located on truck, where such data might be offloaded from the AV to a central data repository for further offline storage, processing, and analysis (e.g., data management, simulation evaluation, etc.).

As shown in FIG. 3, AV 305 is operating (i.e., driving) on a road 310 including lanes 315 and 320, in the direction of travel indicated in the figure. Other vehicles are also traveling on the road, including vehicles 325, 330, and 335, while vehicle 340 is located on the shoulder of the road. Vehicles 325, 330, 335, and 340 need not be autonomous vehicles, although they are not prohibited from being such. AV 305 may be involved in a scenario (i.e., sequence of events) that include one or more actions by the AV. For example, AV 305 may have been driving in lane 320 behind vehicle 325 at a time before scene 300 and changed from lane 320 to lane 315 to arrive at the position shown in scene 300 where AV 305 is passing vehicle 325. Actions performed by AV 305 to pass vehicle 325 may comprise a scenario referred to as a lane change. As an example, the actions associated with the lane change scenario might include, based on the different sensors located on AV 305, determining a speed of vehicle 325 before AV initiates the lane change, the relative position of any other vehicles (e.g., 330 and 335) in the vicinity of AV 305, a current speed of AV 305, a speed limit for the road 310, and other operating states of AV 305; and driving from lane 320 to lane 315, as specified by system requirements for AV 305 to perform a lane change in a safe and controlled manner. The “lane change” scenario is just one example of a scenario that might invoke one or more actions to be performed by AV 305. Another scenario might include a “vehicle on shoulder” scenario wherein another vehicle (e.g., vehicle 340) might be located off but near the road in the shoulder area. In this scenario, AV 305 might be configured to perform one or more actions based on information from the different sensors located thereon, including, for example, determining the dimensions of the vehicle, the type of the vehicle (e.g., emergency, non-emergency vehicle, etc.), how far the vehicle is located from the shoulder lane boundary, whether or not there are pedestrians in the vicinity of the vehicle, determining whether vehicle 340 is moving and if so, at what speed and direction. There may be other scenarios in which AV 305 might operate, including, but not limited to, a lane merge scenario, a cut-in scenario, and an approaching slow or stopped traffic scenario.

In some aspects, a scenario herein may invoke or otherwise should cause an AV herein to perform one or more actions in response to operating to navigate the scenario. The one or more actions may be associated with one or more requirements or criteria that specify a standard by which a performance of the AV may be judged to ascertain whether the AV's performance satisfies the requirements associated with the scenario. For instance, in the example of a lane change scenario there may be a plurality of requirements including, for example, maximum wait time for a gap, lane change duration, when to yield for rear approaching vehicles, etc. In some embodiments, requirements associated with the actions of a scenario may be defined to specify standards for judging whether an AV's performance satisfies (i.e., passes or fails) the requirements associated with the scenario. In some aspects, the performance of an AV associated with a scenario may be deemed to pass if the AV's performance satisfies all of the requirements of the subject scenario. That is, if the performance of the AV associated with the scenario fails any one of the subject scenario's requirements, then the AV's performance may be deemed to have failed the scenario. In some other instances, the performance of an AV associated with a scenario may be deemed to pass the scenario if the AV's performance satisfies one or more designated “key” requirements of the subject scenario.

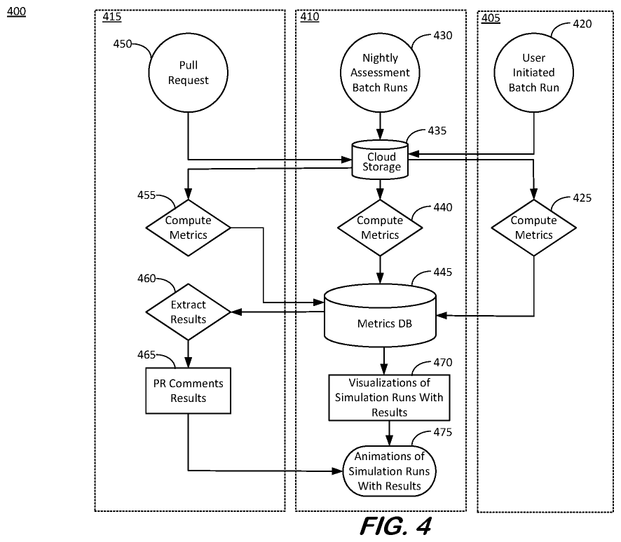

In some aspects, one or more embodiments of the present disclosure might be implemented to execute a number of simulations related to AVs (autonomous vehicles) and automatically evaluate the executed simulations based on a set of one or requirements defined for one or more actions performed by the AVs. FIG. 4 is an illustrative depiction of a framework 400 for a simulation pipeline, in accordance with an example embodiment. Framework 400 includes mechanisms to evaluate an executed simulation of an AV's operational performance against a set of one or more requirements and mechanisms to output results of the evaluation in one or more formats. In some aspects, the results of the evaluation may be presented such that the performance of the AV in the simulation is readily and easily ascertained, whether the results are presented in a textual listing, a tabular listing, a graphical representation (i.e., a dashboard or user interface including, at least in part, graphical representations of the evaluation results), an animation of the executed simulation (e.g., a “replay” of the simulation), other visualization formats, and combinations thereof.

In some embodiments, framework 400 may be capable of evaluating one or more different scenarios. In some instances, a scenario herein may be interchangeably referred to as a feature, where a feature tested by a simulation evaluation pipeline is the same as evaluating the actions of a scenario. For example, a feature may refer to a lane change, a cut-in, a lane merge, and other types of scenarios. In some instances, framework 400 may be efficiently used to test one or more features. In some aspects, framework 400 might include the testing of one or more feature(s), wherein the requirements are defined and may vary in association or correspondence with each particular feature or scenario being evaluated during an executed simulation.

In some aspects herein, a simulation of a performance of an AV might be executed using a simulation application, system, or service. In some instances, the application, system, or service may be provided by a third-party vendor or provider of such products or services (e.g., an off-the-shelf product or commercially available service). Framework 400 may be configured to interface with these (and other) such products or services. In some regards, the simulation application, system, or service might include internal evaluator(s) to execute a simulation based on a set of performance data obtained from an AV.

Framework 400 supports and provides a mechanism for external evaluators to evaluate executed simulations for an AV based on (i.e., using) defined requirements for one or more scenarios. A simulation evaluation pipeline implemented in accordance with framework 400 might automatically generate an output indicating whether the executed simulation passes or fails to meet or otherwise satisfy the defined requirements. In some instances herein, the external evaluators provided by framework 400 may simply be referred to as evaluators.

Referring to FIG. 4, the simulation framework 400 may be configured to accommodate a number of different use cases. As an example, framework 400 is shown as being divided into three use cases, 405, 410, and 415. Use cases 405, 410, and 415 generally correspond to different usage environments for a software application, system, or service implementation of aspects disclosed herein. In some embodiments, framework 400 might be configured to support additional, fewer, or alternative use cases than those specifically depicted in FIG. 4.

Use case 405 of framework 400 includes a progressive testing workflow, which may also be referred to as ad hoc testing. In this use case, a user (e.g., an AV engineer, etc.) may be developing a new feature, algorithm, or version of a feature to be tested by a simulation evaluation pipeline herein. In some instances, it might be desirable to have the individual user run the relevant features or scenarios they are developing on their own to verify whether they pass the corresponding requirements before they create a pull request to have the newly developed feature considered for inclusion in the simulation evaluation pipeline. As shown in FIG. 4, a user might request or otherwise trigger a run or execution of one or more simulations to test the feature(s) they are creating at 420. In response to the request, a set of data (e.g., one or more data records or other data structures) may be retrieved from a memory or data storage facility 435 (e.g., a cloud storage, a data lake, etc.). The data retrieved from storage facility 435 may include operational data related to an AV and operations of the AV in different scenarios. In some aspects, the AV related data may be generated by the numerous sensors and data collections systems deployed on the AV. The AV related data may include time series data, wherein data points have an associated timestamp that is indicative of the time the parameter represented by each data point occurred. At an operation 425, an external, offline evaluator (i.e., evaluator) is applied against the retrieved data using a set of requirements defined for and corresponding to the feature(s) being tested in use case 405. The results of the evaluation may be stored in a metrics database 445 for further analysis and processing.

Use case 410 of framework 400 includes a scheduled assessment workflow, where a software branch might be tested at scheduled intervals, such as every night. In use case 410, new features or changes to features since a previous testing may be tested by a simulation evaluation pipeline herein to ensure that the performance of the simulation development is not regressing and is not otherwise faulty. As illustrated in FIG. 4, a scheduled execution of one or more simulations to test the new feature(s) is initiated at 430 and a set of data may be retrieved from data storage facility 435 in response thereto. The data retrieved from storage facility 435, representing AV operations in different scenarios, may be used by an evaluator at operation 440 to test whether the new feature(s) pass a set of requirements defined for and corresponding to the feature(s) being tested. The results of the evaluation may be stored in metrics database 445 for further analysis and processing.

Use case 415 of framework 400 includes a continuous integration workflow 415, where simulations are executed in response to a pull request (PR) being created. Workflow 415 may be created to ensure that the requirements for new or update feature(s) satisfy (i.e., pass) the defined requirements corresponding thereto before software implementing the new or updated feature(s) are merged by the PR into the main branch for the simulation evaluation pipeline. Referring to FIG. 4, a PR is initiated at 450 and a set of data may be retrieved from data storage facility 435 in response thereto. The data retrieved from storage facility 435 may be used by an evaluator at operation 455 to test whether the new feature(s) associated with the PR pass a set of requirements defined for and corresponding to the feature(s) being tested. The results of the evaluation may be stored in metrics database 445 for further analysis and processing. Results of the simulation evaluation at operation 455 and stored in metrics database 445 may be monitored and extracted at operation 460. PR comment(s) with high level pass/fail results (e.g., a summary of the evaluation result, list of scenarios with pass/fail indication, link to animations of simulation runs 475, etc.) may be generated at operation 465.

In some instances, central metrics database 445 may include a central repository where all metrics tracked by an AV provider are stored. In some aspects, metrics database 445 includes evaluation results produced by each of the three workflows 405, 410, and 415. In some aspects, the requirements and metrics generated by different workflows comprising simulation pipeline framework 400 may be the same. The simulation metrics may go into the same central metrics database following a structure that allows for a comparison between on-road data/scenarios and simulation data/scenarios. For the different use-cases 405, 410, and 415, the metrics data generated by each workflow may also be saved in the same database, in the same format (i.e., schema) so that data between use cases can be readily analyzed relative to each other.

In some aspects, a common shared aspect of the three work workflows in framework 400 is that the offline evaluator(s) therein uses, for example, the same code to evaluate requirements in each of the three workstreams. While the processing flow in each workflow may be different, the requirements are the same and requirement checking functions are the same for on-road data and executed simulations. In this manner, features, evaluators, and results from executed simulations may be compared to each other, despite the different workflows that might produce, for example, the executed simulation results.

In some embodiments, there may be two types of simulations executed within framework 400 (e.g., by a third-party platform simulator). One type includes, for example, a logstream simulation that includes a replay or re-simulation of an on-road scenario using on-road AV generated and collected data. A second type is a synthetic simulation that may include a scenario that is manually or otherwise synthetically created by a system or entity (e.g., simulation operations engineer(s)). In some instances of testing herein, the evaluators of framework 400 may be executed against both types of simulations. In other instances, depending on a particular application, the evaluator may be run against one or the other type of simulation.

In some embodiments, a query may be executed against metrics database 445 to produce or otherwise generate a visualization of simulation runs including the evaluation of the executed simulation runs. In some instances, the visualizations might be produced by or in part by an analytics application, system, or service that analyzes the metrics database data to provide insight into the meaning and relationships within the metrics data. In some embodiments, the visualizations may include presentations having, for example, interactive tables, charts, graphs, dashboards, and combinations thereof. The visualizations 470 may be further linked to or otherwise associated with a system, application, platform, or service 475 to generate and present replay animations of the executed simulation runs with the evaluation results presented in combination with the animations.

In an example embodiment herein, a visualization including a dashboard to view on-road test data or the like might also be used to present simulation data. In some instances, the dashboard may include a user interface (UI) or other tool including views of on-road test data and the results of an evaluation of executed simulations may be also viewed in the same UI or tool. In this example, visualizations presenting, for example, AV camera data, the AV driving in different scenarios, etc. might also include a 3-D presentation of the AV throughout a run and a simulated run. In some instances, the dashboard might include a presentation of the evaluator data in conjunction with the replay of the simulation so that a viewer thereof can easily see the behavior of the AV, the evaluator data including an indicated pass/failure and associated timestamp, what aspect failed, etc., where these different aspects might be presented in a same UI.

As noted previously, the (external) evaluators of framework 400 used at operations 425, 440, and 460 to evaluate executed simulations are separate and distinct from any internal evaluator comprising a simulation application, system, or service that may be used to execute a simulation. A number of advantages and benefits are provided by this aspect of framework 400. For example, the same evaluators used to evaluate executed simulations using on-road data related to an AV (e.g., retrieved from storage facility 435) may also be used to evaluate simulations executed using synthetically produced simulation data. In this manner, evaluations of executed simulations based on real-world, on-road AV data may be compared with executed simulations based on synthetically produced AV data. In one example application, the quantity, diversity, or quality of the on-road AV data including certain feature(s) might be limited, whereas a sufficient set of synthetic data might be generated and evaluated to form some conclusions regarding whether a feature(s) passes a set of requirements. In this example where the on-road data might be limited, the evaluations of executed simulations using this limited data may be useful in an analysis/comparison with the evaluations using the synthetic AV data to, at least, confirm the applicability of the requirements to both on-road and synthetic data, as well as confirm an acceptable evaluation for both the on-road and synthetic contexts (since the requirements are the same for each).

In some embodiments, an entity implementing aspects of framework 400 may maintain the code base including the evaluators therein. In some aspects, a benefit for an entity to own and maintain a simulation evaluation pipeline framework or platform herein is that as the entity develops and iterates through new system requirements, such requirements can be quickly reflected in the pipeline simulation evaluators of framework 400. For example, the entity need not make a request to another party or entity (e.g., a third-party software vendor or service provider) to provide, if at all, a patch or upgrade including the new system requirements.

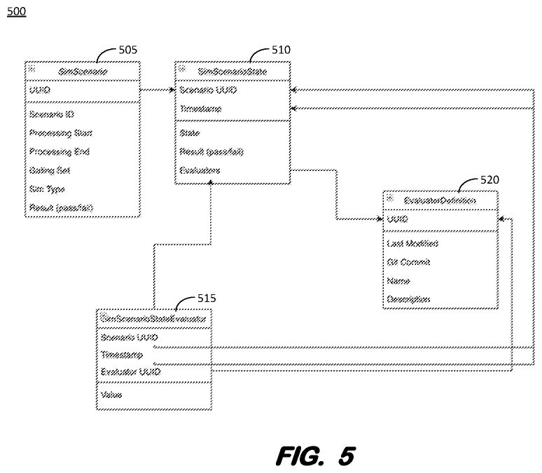

FIG. 5 is an illustrative depiction of a database schema 500, in accordance with an example embodiment. In some aspects, database schema 500 may relate to the design of a database for metrics data in some example embodiments herein (e.g., FIG. 4, metrics database 445). In some aspects, the structures depicted in FIG. 5 may be similar to a database schema used for on-road scenarios related to an AV. Accordingly, a simulation data store organized per the database schema 500 may be easily compared with on-road performance data having a similar database schema. Data structure 505 is a simulation scenario table and may store data including universally unique identifier for each scenario, a scenario ID (identifier), a start timestamp, a stop timestamp, and other high level information including, for example, a simulation type (e.g., either synthetic or logstream) and an indication of an evaluation result for the scenario (e.g., pass/fail). For each scenario, there is a simulation scenario state table 510 that is updated at each timestamp and includes, for example, the pass/fail information for the associated evaluator(s) executed at each timestamp. In some aspects, if a scenario passes a requirement, then at each timestamp the state for the scenario should be “pass”. In some aspects, if there is a failure at one or more (key) timestamps, then the scenario fails. In some aspects, database structure 500 is able to store data at a granular level (i.e., at each timestamp) as represented by data structure 510 and at an aggregate level for a scenario as represented by data structure 505.

For each scenario herein, there may be one or more associated evaluators. There may be one evaluator for each requirement associated with a subject scenario. Accordingly, multiple requirements will correspond to multiple evaluators. A simulation scenario state evaluator data structure 515 may be provided for each evaluator. This data structure may be used to track each evaluator associated with a scenario and store the result of the execution of that evaluator. That is, a scenario may comprise or be associated with multiple requirements and each requirement is evaluated at each timestamp, where applicable for a given scenario. As such, multiple evaluators could be applied/used at a given timestamp. Data structure 515 may be used to keep track of the evaluators used at each timestamp, including whether they pass/fail at that timestamp.

Data structure 520 is an evaluator definition table and may be provided to include values for parameters defining an evaluator. As shown, data structure 520 may include for each evaluator, a UUID, an indication of when it was last updated, a name for the evaluator, a description of the evaluator, and other information.

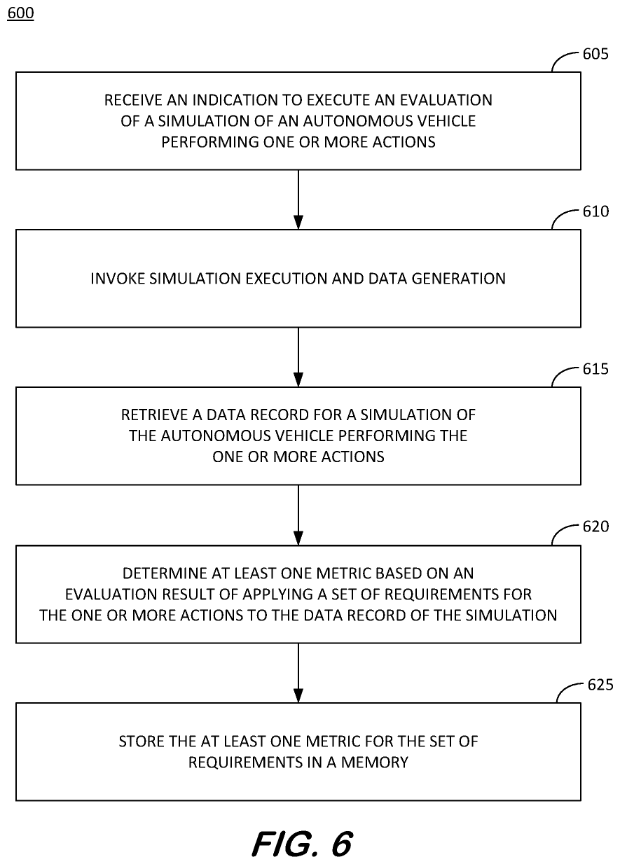

FIG. 6 is an illustrative flow diagram of an example of a simulation evaluation pipeline process 600, in accordance with an example embodiment. In some embodiments, a framework or architecture disclosed herein might be used to implement some aspects of process 600. At operation 605 an indication to execute an evaluation of a simulation of an AV performing one or more actions might be received by a system, application, or service implementing process 600. At operation 610, in response to receiving the indication to execute an evaluation of a simulation, the simulation evaluation and data generation related thereto is invoked at operation 610. As demonstrated in conjunction with FIG. 4 above, the indication received might vary and originate from different entities depending on, for example, a workflow or use case being performed. Referring to the example of FIG. 4, the workflows might correspond, but are not necessarily limited to, a user initiated testing workflow, a scheduled assessment workflow, and a continuous integration workflow.

At operation 615, a data record of a simulation for the AV performing the one or more actions of a scenario may be retrieved from a data storage facility. The data storage facility might include or be similar to the cloud stage device or system 435 disclosed in FIG. 4.

Continuing to operation 620, at least one metric based on a result of an evaluation of an executed simulation for the AV is determined. Operation 620 may include applying a set of requirements for the one or more actions of the executed simulation to the data record of the simulation to obtain an indication of whether the scenario satisfies or passes the set of requirements.

At operation 625, at least one metric for the set of requirements determined at operation 620 may be stored in a memory (e.g., FIG. 4, metrics database 445). In some embodiments, the at least one memory stored in the memory might be organized as discussed above regarding the database schema depicted in FIG. 5, though not limited thereto. For example, the memory storing the at least one metric for the set of requirements might be organized to include a data structure defining an aggregate scenario comprising a simulation scenario including the one or more actions performed by the autonomous vehicle; a data structure defining a state for each timestamp of a simulation scenario including the one or more actions performed by the autonomous vehicle; a data structure defining an evaluator to use for each timestamp of a simulation scenario including the one or more actions performed by the autonomous vehicle; and a data structure defining a specification for an evaluator to be applied to a simulation scenario including the one or more actions performed by the autonomous vehicle.

Process 600 may, in some embodiments, include additional, fewer, or alternative operations, including combinations with one or more of the operations shown in FIG. 6. In one embodiment, process 600 may further include an operation to define the set of requirements for the one or more actions performed by an AV herein. This operation of defining the set of requirements might be performed independently of or in conjunction with one of the operations of process 600. For example, the defining of the set of requirements for the one or more actions might be accomplished prior to operations 605 or 610 or performed with or in parallel therewith.

In some aspects, process 600 and framework 400 might be configured to process batch runs and batch comparisons of executed simulations. For example, framework 400 and process 600 might provide a mechanism to examine an aggregate of scenarios (i.e., a batch of scenarios), including, for example, multiple (e.g., 100) different simulations of a scenario to allow a comparison of the multiple different simulations.

In one embodiment, the operations of process 600 might be executed for a plurality of simulations such that process 600 can include receiving an indication to execute an evaluation of a plurality of simulations of at least one autonomous vehicle performing one or more actions; retrieving data records for a set of simulations of the autonomous vehicle performing the one or more actions; determining at least one metric associated with an evaluation result of applying a set of requirements for the one or more actions to the data records of the plurality of simulations; and storing the at least one metric for each of the set of requirements in a memory.

In some instances, simulation evaluations including batch operations may be supported and provided by some embodiments herein. In some aspects, a goal of batch comparisons in one example embodiment might be to understand the performance difference between different versions of software for an AV. For example, batches of simulation evaluations might be run on different versions of AV software, wherein the same evaluator code is used to evaluate all of the simulations. As an example related to a batch operation herein, a batch of 100 simulation evaluations might be run for an AV executing a first version of AV software and a second batch of the same 100 simulation evaluations might be executed for the AV running a second version of the AV software. A comparison of the results of each batch run may be analyzed to determine the results of each run and to ascertain contrasts/similarities therebetween, which batch run was better (i.e., which version of the AV software performed closer to an expected result), etc.

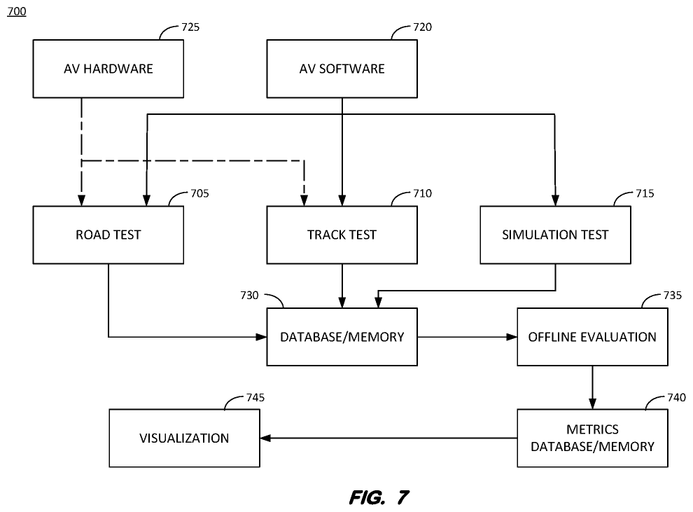

FIG. 7 is an illustrative example of an architecture or environment in which aspects of the present disclosure may be applied, in some embodiments herein. In the example of FIG. 7, three (3) streams of data may be generated and used by a simulation evaluation pipeline herein. The streams of data may include road test data 705 that is generated by an AV during on-road (i.e., real world) runs; track test data 710 generated by an AV operating on a track, closed course, or otherwise controlled testing environment; and simulation test data 715 that may be synthetically generated within a software environment. As shown, all three streams of data 705, 710, and 715 are generated based on the AV software 720. Road test data 705 and track test data 710 are also generated based on the AV hardware since each is based on actual performance runs of the AV, whereas simulation test data is synthetically generated. The different streams of data 705, 710, and 715 may be stored in a database or memory 730. Data from database/memory 730 (either logstream road test data 705 and track test data 710 or synthetic simulation test data 715) may be accessed and used by an offline evaluation pipeline 735, in accordance with other aspects disclosed herein (e.g., framework 400, process 600). Results from the simulation evaluation 735 may be stored in a metrics database or memory facility 740. In some embodiments, the results of the simulation evaluation might be extracted from metrics database or memory facility 740 and processed to generate a visualization 745 (e.g., an interactive dashboard, an animation of a simulation run including, for example, detailed metrics and object labeling at one or more timestamps, etc.).

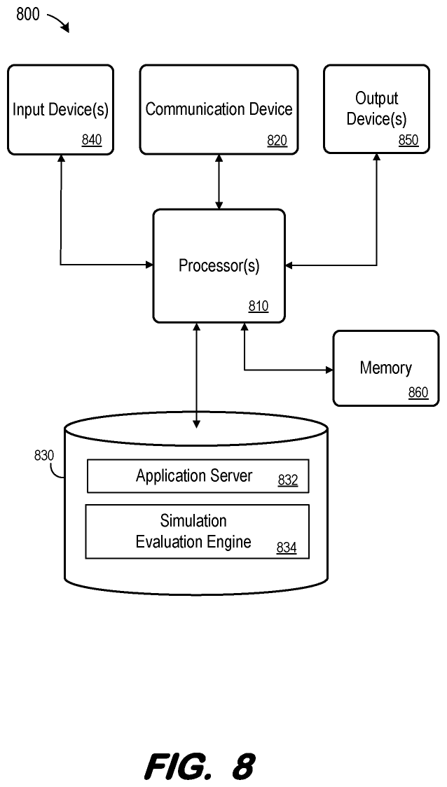

FIG. 8 illustrates a computing system 800 that may be used in any of the architectures or frameworks (e.g., FIG. 4, FIG. 7) and processes (e.g., FIG. 6) disclosed herein, in accordance with an example embodiment. FIG. 8 is a block diagram of server node 800 embodying a simulation evaluation engine, according to some embodiments. Computing system 800 may comprise a general-purpose computing apparatus and may execute program code to perform any of the functions described herein. Computing system 800 may include other unshown elements according to some embodiments.

Computing system 800 includes processing unit(s) 810 operatively coupled to communication device 820, data storage device 830, one or more input devices 840, one or more output devices 850, and memory 860. Communication device 820 may facilitate communication with external devices, such as an external network, a data storage device (e.g., a database or memory storing logstream and synthetic data, a metrics database or memory), or other data source. Input device(s) 840 may comprise, for example, a keyboard, a keypad, a mouse or other pointing device, a microphone, knob or a switch, an infra-red (IR) port, a docking station, and/or a touch screen. Input device(s) 840 may be used, for example, to enter information into computing system 800. Output device(s) 850 may comprise, for example, a display (e.g., a display screen) a speaker, and/or a printer.

Data storage device 830 may comprise any appropriate persistent storage device, including combinations of magnetic storage devices (e.g., magnetic tape, hard disk drives and flash memory), optical storage devices, Read Only Memory (ROM) devices, etc., while memory 860 may comprise Random Access Memory (RAM).

Application server 832 may each comprise program code executed by processor(s) 810 to cause computing system 800 to perform any one or more of the processes described herein. Embodiments are not limited to execution of these processes by a single computing device. Data storage device 830 may also store data and other program code for providing additional functionality and/or which are necessary for operation of computing system 800, such as device drivers, operating system files, etc. Simulation evaluation engine 834 may include program code executed by processor(s) 810 to evaluate simulations based on requirements, as disclosed in various embodiments herein. Results generated by the simulation evaluation engine 834 may be stored in a central metrics database (not shown in FIG. 8) via communication device 820.

As will be appreciated based on the foregoing specification, the above-described examples of the disclosure may be implemented using computer programming or engineering techniques including computer software, firmware, hardware or any combination or subset thereof. Any such resulting program, having computer-readable code, may be embodied or provided within one or more non-transitory computer-readable media, thereby making a computer program product, i.e., an article of manufacture, according to the discussed examples of the disclosure. For example, the non-transitory computer-readable media may be, but is not limited to, a fixed drive, diskette, optical disk, magnetic tape, flash memory, external drive, semiconductor memory such as read-only memory (ROM), random-access memory (RAM), and/or any other non-transitory transmitting and/or receiving medium such as the Internet, cloud storage, the Internet of Things (IoT), or other communication network or link. The article of manufacture containing the computer code may be made and/or used by executing the code directly from one medium, by copying the code from one medium to another medium, or by transmitting the code over a network.

The computer programs (also referred to as programs, software, software applications, “apps”, or code) may include machine instructions for a programmable processor and may be implemented in a high-level procedural and/or object-oriented programming language, and/or in assembly/machine language. As used herein, the terms “machine-readable medium” and “computer-readable medium” refer to any computer program product, apparatus, cloud storage, internet of things, and/or device (e.g., magnetic discs, optical disks, memory, programmable logic devices (PLDs)) used to provide machine instructions and/or data to a programmable processor, including a machine-readable medium that receives machine instructions as a machine-readable signal. The “machine-readable medium” and “computer-readable medium,” however, do not include transitory signals. The term “machine-readable signal” refers to any signal that may be used to provide machine instructions and/or any other kind of data to a programmable processor.

The above descriptions and illustrations of processes herein should not be considered to imply a fixed order for performing the process steps. Rather, the process steps may be performed in any order that is practicable, including simultaneous performance of at least some steps. Although the disclosure has been described in connection with specific examples, it should be understood that various changes, substitutions, and alterations apparent to those skilled in the art can be made to the disclosed embodiments without departing from the spirit and scope of the disclosure as set forth in the appended claims.

1. A system comprising:
a memory storing computer instructions; and
a processor communicatively coupled with the memory to execute the instructions and capable of:
receiving an indication to execute an evaluation of a simulation of an autonomous vehicle performing one or more actions;
retrieving a data record for the simulation of the autonomous vehicle performing the one or more actions, the data record being retrieved from a memory including a first data record generated by the autonomous vehicle executing an autonomous vehicle software using real world test data and a second data record generated by the autonomous vehicle software using synthetically generated test data;
executing, by a computing device processor, the evaluation of the simulation of the autonomous vehicle performing the one or more actions by applying a set of requirements defined for the one or more actions to the first and second data records generated by the execution of the autonomous vehicle software, to generate an evaluation result;
determining, by the computing device processor, at least one metric based on the evaluation result; and
storing the at least one metric in a second memory.

2. The system of claim 1, wherein the indication to execute the evaluation of the simulation of the autonomous vehicle is received from at least one of a user initiated testing workflow, a scheduled assessment workflow, and a continuous integration workflow.

3. The system of claim 1, wherein the at least one metric includes an indication of whether the data record for the simulation the autonomous vehicle performing the one or more actions passed or failed the evaluation based on the set of requirements.

4. The system of claim 1, wherein the first data record of the simulation of the autonomous vehicle performing the one or more actions includes time series data having at least a start timestamp for a start of the one or more actions performed by the autonomous vehicle and a stop timestamp for an end of the one or more actions performed by the autonomous vehicle.

5. The system of claim 1, wherein the second memory storing the at least one metric further comprises:
a data structure defining an aggregate scenario comprising a simulation scenario including the one or more actions performed by the autonomous vehicle;
a data structure defining a state for each timestamp, of one or more timestamps, of the simulation scenario including the one or more actions performed by the autonomous vehicle;
a data structure defining an evaluator to use for each of the timestamps of the simulation scenario including the one or more actions performed by the autonomous vehicle; and
a data structure defining a specification for the evaluator to be applied to the simulation scenario including the one or more actions performed by the autonomous vehicle.

6. The system of claim 1, wherein the processor communicatively coupled with the memory is further capable of defining the set of requirements.

7. The system of claim 1, wherein the processor communicatively coupled with the memory is further capable of:
receiving an indication to execute a second evaluation of a plurality of simulations of at least one autonomous vehicle performing a second one or more actions;
retrieving a set of data records for a set of simulations of the at least one autonomous vehicle performing the second one or more actions, the data records for the set of simulations being retrieved from a memory including a third data record generated by the at least one autonomous vehicle executing the autonomous vehicle software using real world test data and a fourth data record generated by the autonomous vehicle software using synthetically generated test data;
executing, by the computing device processor, the second evaluation of the plurality of simulations of the at least one autonomous vehicle performing the second one or more actions by applying a set of requirements defined for the second one or more actions to the third and fourth data records of the set of simulations generated by the execution of the autonomous vehicle software, to generate a second evaluation result;
determining, by the computing device processor, a second at least one metric associated with the second evaluation result; and
storing the second at least one metric associated with the second evaluation result for each of the set of requirements in the second memory.

8. The system of claim 1, wherein the processor communicatively coupled with the memory is further capable of generating an output based on the at least one metric, the output including at least one of a textual listing, a tabular listing, a graphical representation of the at least one metric, an animation including a representation of the at least one metric, and combinations thereof.

9. A method comprising:
receiving an indication to execute an evaluation of a simulation of an autonomous vehicle performing one or more actions;
retrieving a data record for the simulation of the autonomous vehicle performing the one or more actions, the data record being retrieved from a memory including a first data record generated by the autonomous vehicle executing an autonomous vehicle software using real world test data and a second data record generated by the autonomous vehicle software using synthetically generated test data;
executing, by a computing device processor, the evaluation of the simulation of the autonomous vehicle performing the one or more actions by applying a set of requirements defined for the one or more actions to the first and second data records generated by the execution of the autonomous vehicle software, to generate an evaluation result;
determining, by the computing device processor, at least one metric based on the evaluation result; and
storing the at least one metric in a second memory.

10. The method of claim 9, wherein the indication to execute the evaluation of the simulation of the autonomous vehicle is received from at least one of a user initiated testing workflow, a scheduled assessment workflow, and a continuous integration workflow.

11. The method of claim 9, wherein the at least one metric includes an indication of whether the data record the simulation for the simulation of the autonomous vehicle performing the one or more actions passed or failed the evaluation based on the set of requirements.

12. The method of claim 9, wherein the first data record of the simulation of the autonomous vehicle performing the one or more actions includes time series data having at least a start timestamp for a start of the one or more actions performed by the autonomous vehicle and a stop timestamp for an end of the one or more actions performed by the autonomous vehicle.

13. The method of claim 9, wherein the second memory storing the at least one metric further comprises:
a data structure defining an aggregate scenario comprising a simulation scenario including the one or more actions performed by the autonomous vehicle;
a data structure defining a state for each timestamp, of one or more timestamps, of the simulation scenario including the one or more actions performed by the autonomous vehicle;
a data structure defining an evaluator to use for each of the timestamps of the simulation scenario including the one or more actions performed by the autonomous vehicle; and
a data structure defining a specification for the evaluator to be applied to the simulation scenario including the one or more actions performed by the autonomous vehicle.

14. The method of claim 9, further comprising defining the set of requirements.

15. The method of claim 9, further comprising:
receiving an indication to execute a second evaluation of a plurality of simulations of at least one autonomous vehicle performing a second one or more actions;
retrieving a set of data records for a set of simulations of the at least one autonomous vehicle performing the second one or more actions, the data records for the set of simulations being retrieved from the memory including a third data record generated by the at least one autonomous vehicle executing the autonomous vehicle software using real world test data and a fourth data record generated by the autonomous vehicle software using synthetically generated test data;
executing, by the computing device processor, the second evaluation of the plurality of simulations of the at least one autonomous vehicle performing the second one or more actions by applying a set of requirements defined for the second one or more actions to the third and fourth data records of the set of simulations generated by the execution of the autonomous vehicle software, to generate a second evaluation result;
determining, by the computing device processor, a second at least one metric associated with the second evaluation result; and
storing the second at least one metric associated with the second evaluation result for each of the set of requirements in the second memory.

16. The method of claim 9, further comprising generating an output based on the at least one metric, the output including at least one of a textual listing, a tabular listing, a graphical representation of the at least one metric, an animation including a representation of the at least one metric, and combinations thereof.

17. A non-transitory medium having processor-executable instructions stored thereon, the medium comprising:
instructions to receive an indication to execute an evaluation of a simulation of an autonomous vehicle performing one or more actions;
instructions to retrieve a data record for the simulation of the autonomous vehicle performing the one or more actions, the data record being retrieved from a memory including a first data record generated by the autonomous vehicle executing an autonomous vehicle software using real world test data and a second data record generated by the autonomous vehicle software using synthetically generated test data;
instructions to execute the evaluation of the simulation of the autonomous vehicle performing the one or more actions by applying a set of requirements defined for the one or more actions to the first and second data record generated by the execution of the autonomous vehicle software, to generate an evaluation result;
instructions to determine at least one metric based on the evaluation result; and
instructions to store the at least one metric in a second memory.

18. The medium of claim 17, wherein the second memory storing the at least one metric further comprises:
a data structure defining an aggregate scenario comprising a simulation scenario including the one or more actions performed by the autonomous vehicle;
a data structure defining a state for each timestamp, of one or more timestamps, of the simulation scenario including the one or more actions performed by the autonomous vehicle;
a data structure defining an evaluator to use for each of the timestamps of the simulation scenario including the one or more actions performed by the autonomous vehicle; and
a data structure defining a specification for the evaluator to be applied to the simulation scenario including the one or more actions performed by the autonomous vehicle.

19. The medium of claim 17, further comprising instructions to define the set of requirements.

20. The medium of claim 17, further comprising instructions to:
receive an indication to execute a second evaluation of a plurality of simulations of at least one autonomous vehicle performing a second one or more actions;
retrieve data records for a set of simulations of the at least one autonomous vehicle performing the second one or more actions, the data records for the set of simulations being retrieved from the memory including a third data record generated by the at least one autonomous vehicle executing the autonomous vehicle software using real world test data and a fourth data record generated by the autonomous vehicle software using synthetically generated test data;
execute the second evaluation of the plurality of simulations of the at least one autonomous vehicle performing the second one or more actions by applying a set of requirements defined for the second one or more actions to the third and fourth data records of the set of simulations generated by the execution of the autonomous vehicle software, to generate a second evaluation result;
determine a second at least one metric associated with the second evaluation result; and
store the second at least one metric associated with the second evaluation result for each of the set of requirements in the second memory.
